(19) United States
(12) Patent Application Publication
(10) Pub. No.: US 2017/0054045 A1
(43) Pub. Date: Feb. 23, 2017

(54) METHOD FOR PACKAGING SOLAR CELL DEVICE AND STRUCTURE THEREOF

(71) Applicant: INSTITUTE OF NUCLEAR ENERGY RESEARCH, ATOMIC ENERGY COUNCIL, EXECUTIVE YUAN, R.O.C., TAOYUAN COUNTY (TW)

(72) Inventors: YUEH-MU LEE, TAOYUAN COUNTY (TW); HWEN-FEN HONG, TAOYUAN COUNTY (TW); ZUN-HAO SHIH, TAOYUAN COUNTY (TW); HAO-TING CHIEN, TAOYUAN COUNTY (TW); KE-JEN CHIAN, TAOYUAN COUNTY (TW)

(21) Appl. No.: 14/832,020

(22) Filed: Aug. 21, 2015

(51) Int. Cl. H01L 31/048; H01L 31/18; H01L 31/05

(52) U.S. Cl. CPC H01L 31/048; H01L 31/0516; H01L 31/18

(57) ABSTRACT

The present invention relates to a method for packaging solar cell device and the structure thereof. The structure comprises a substrate formed by glass or insulating high polymer, an insulating layer, a plurality of conductive layers, and a plurality of solar cells. A plurality of conductive films are disposed on a surface of the substrate. The insulating layer is disposed on the substrate and comprises a plurality of holes located on the plurality of conductive films. The plurality of conductive layers are disposed in the plurality of holes. A bottom surface of the plurality of conductive layers is connected electrically with the plurality of conductive films. The plurality of solar cells are disposed on the insulating layer and connected electrically with the top surface of the plurality of conductive layer.

### FIELD OF THE INVENTION

The present invention relates to a method for packaging and the structure thereof, and particularly to a method for packaging a solar cell device and the structure thereof applicable to solar power generation and enabling adoption of lighter and cheaper substrate material and thus making the solar cell modules more competitive.

### BACKGROUND OF THE INVENTION

In order to satisfy the market demand of solar power generation, concentrative solar cell modules are developing in the direction of low cost, low carbon emission, and automation. Nonetheless, most manufacturers still use metal materials, for example, lighter aluminum plates, as the circuit substrates for solar cell arrays. The drawbacks of aluminum plates include more carbon emission during the fabrication process. In addition, because solar cell modules are disposed outdoors, the lifetime of substrates made of metal materials is not acceptable.

While using metal materials as the substrate according to the prior art, in order to extend the lifetime and avoid the safety problem of electric leakage, a complete insulating layer will be added on the substrate made of metal materials as protection. Then the circuit is disposed on the insulating layer. This structure requires a higher manufacturing cost. Besides, it cannot solve the problem of high carbon emission during the fabrication process of components.

Accordingly, in the field, glass is considered as the substrate material. According to the Taiwan Patent Number 1455327, a photovoltaic glass, a method for manufacturing the photovoltaic glass, and a solar cell module having the photovoltaic glass are disclosed. According to the invention, bumps selected from the group consisting of metal oxide, metal sulfide, metal telluride, metal selenide are formed on the glass substrate. By using the bumps formed on the glass substrate, the light with shorter wavelength illuminated into the glass initially can be converted to light with longer wavelength and absorbable by the photoelectric structure. In addition, according the Taiwan Patent Number 1313149, a circuit board module is disclosed. The structure according to the invention includes the stack of a plurality glass circuit boards. By taking advantage of identical thermal expansion coefficients, the influence of thermal stress can be controlled. Moreover, the Taiwan Patent Number 1323485 provides a structure having a semiconductor on an insulator. The structure comprises one or more regions formed by essentially single-crystal semiconductor layers, such as doped silicon, and connected to the supporting substrate formed by oxide glass or oxide glass ceramics. This is an application including glass substrates.

The present invention excludes the need of manufacturing the substrate using metal materials. Instead, the present invention provides a novel method for packaging solar cell device and the structure thereof for applying the advantages of glass to the field of solar power generation.

### SUMMARY

An objective of the present invention is to provide a structure of solar cell device, which uses glass materials or insulating high-polymer materials to manufacture the substrate for carrying solar cells and devices for related circuit structure. By using taking advantage of lightness, low costs, lower carbon footprint, and compatibility with the fabrication process according to the prior art of these materials, the challenges while applying a solar cell module, including weight, cost, and environmental protection, can be reduced, and hence increasing competitiveness in the market.

Another objective of the present invention is to provide a structure of solar cell device, which requires no extra conductive wires by using substrates made of glass materials or insulating high-polymer materials. This succinct structure facilitates fabrication yield and lifetime in application.

A further objective of the present invention is to provide a structure of solar cell device, which does not use massive metal materials as the substrate. Given that solar cell modules are mainly disposed outdoors, the structure is less influenced by moisture and thus slowing down the aging rate of hardware equipment.

Still another objective of the present invention is to provide a method for packaging solar cell device. After preparing substrate modules and solar cell modules, the two are connected. Thereby, it is not necessary to process a single item continuously and hence simplifying the process.

In order to achieve the objectives as described above, the present invention discloses a structure of solar cell device, which comprises a substrate formed by glass or insulating high polymer, an insulating layer, a plurality of conductive layers, and a plurality of solar cells. A plurality of conductive films are disposed on a surface of the substrate. The insulating layer is disposed on the substrate and comprises a plurality of holes located on the plurality of conductive films. The plurality of conductive layers are disposed in the plurality of holes. A bottom surface of the plurality of conductive layers is connected electrically with the plurality of conductive films. The plurality of solar cells are disposed on the insulating layer and connected electrically with the top surface of the plurality of conductive layer.

The method for packaging solar cell device comprises steps of: disposing a plurality of conductive films on a surface of a glass substrate or an insulating high-polymer substrate for forming a substrate module; disposing a plurality of conductive layers in a plurality of holes of an insulating layer, disposing a plurality of solar cells on the insulating layer, and connecting electrically the plurality of solar cells with a top surface of the plurality of conductive layers for forming a cell module; and connecting the cell module and the substrate module such that the cell module is disposed on the substrate module and a bottom surface of the plurality of conductive layers are connected electrically with the plurality of conductive films. The order of preparing the substrate module and the cell module can be arbitrary.

### BRIEF DESCRIPTION OF THE DRAWINGS

FIG. 1 shows a schematic diagram of the structure according a preferred embodiment of the present invention;

FIG. 2 shows an exploded view of the structure according a preferred embodiment of the present invention;

FIG. 3 shows a cross-sectional view of the structure according another preferred embodiment of the present invention; and

FIG. 4 shows a flowchart of the structure according a preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

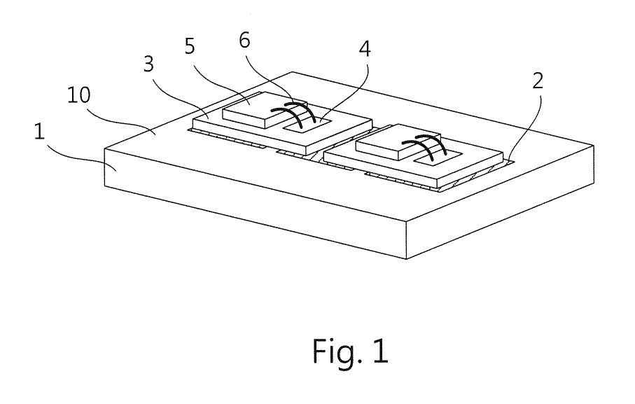

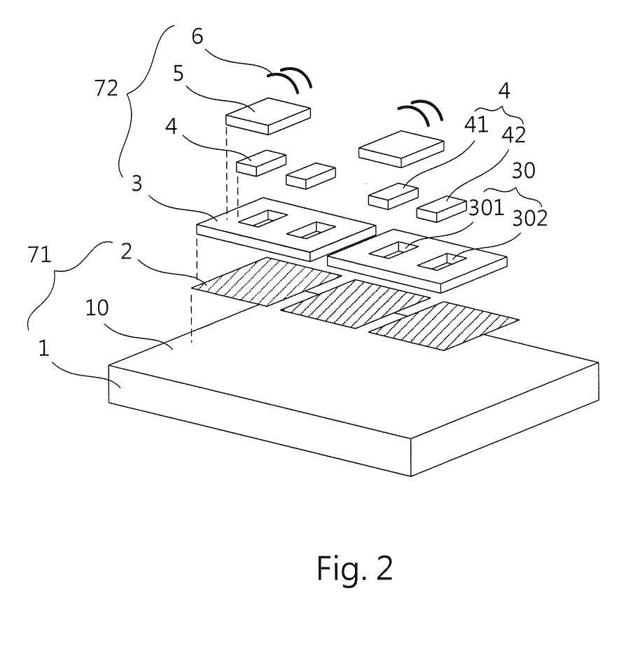

Please refer to FIG. 1 and FIG. 2, which show a schematic diagram and an exploded view of the structure according a preferred embodiment of the present invention. The structure of the solar cell device according to the present invention comprises a glass substrate 1, a plurality of conductive films 2, an insulating layer 3, a plurality of conductive layers, and a plurality of solar cells 5. The plurality of conductive films 2 are disposed on a glass surface 10 of the glass substrate 1. The insulating layer 3 is disposed on the glass substrate 1. The plurality of conductive layers 4 are disposed in a plurality of holes 30 of the insulating layer 3. Besides, the plurality of solar cells 5 are disposed on the insulating layer 3.

According to a preferred embodiment of the present invention, the adopted material for the substrate is glass. In the fabrication process of glass, 1.14 kilograms of carbon dioxide are emitted for each kilogram of the product, which is much less than 10.10 kilograms of carbon dioxide for each kilogram of aluminum material. Thereby, selecting glass as the substrate material can apparently reduce the carbon footprint of solar cell modules. In addition, the density of glass is 2.5 grams per cubic centimeters, which is smaller than the density of aluminum, 2.71 grams per cubic centimeters. Hence, the total weight of a solar cell module can be reduced. In other words, under a given volume, the load of the support structure for solar cell module can be reduced and thereby lowering the cost for hardware disposition. Moreover, glass has an excellent insulating property, eliminating the necessity of further processing the substrate for improving its insulating property and thus enhancing the competitive advantage of the product. Besides, the glass can be normal glass or fortified glass.

According another preferred embodiment of the present invention, an insulating high-polymer substrate formed by insulating high-polymer materials can be adopted. Thanks to its characteristics of plastics, it is superior to an aluminum substrate in terms of the weight per unit volume, the manufacturing cost, and the insulating property. Thereby, it can be used as another material for improving the competitive advantage of products.

The plurality of conductive films 2 for circuits are disposed on the glass surface 10 of the glass substrate 1. They are isolated from one another and are used for connecting different solar cells. The plurality of conductive films 2 can be disposed on the glass surface through physical or chemical methods. Besides, depending on the requirement of connecting the cells in series, the sizes can be adjusted based on FIGS. 1 and 2 for increasing the number of solar cells connected in series.

The material of the insulating layer 3 can be selected from the insulating materials such as aluminum oxide (Al₂O₃) or aluminum nitride (AlN) and be in the form of a ceramic substrate suitable for high-temperature and high-humidity environments. In addition, the ceramic substrate also has the characteristics of high thermal conductivity, high thermal endurance, high erosion and wear resistance, anti-ultraviolet light, and anti-yellowing. The insulating layer 3 can be a single large-area ceramic substrate or a plurality of small-area ceramic substrates. According to the present preferred embodiment, a plurality of small-area ceramic substrates are adopted to form the insulating layer 3. As shown in the figures, each ceramic substrate has two holes 30, respectively. The conductive layer 4 fills the holes 30, respectively, for conducting the positive and negative electrodes.

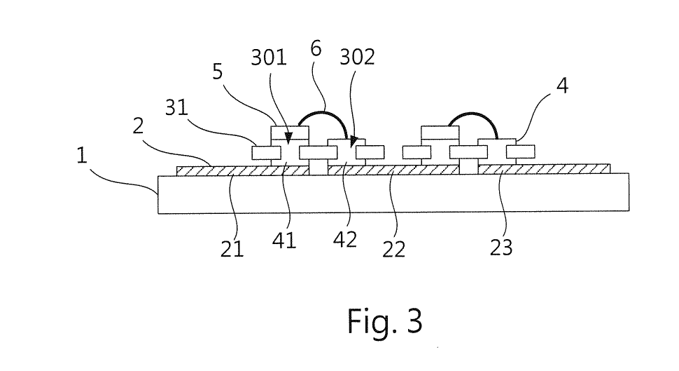

Furthermore, please refer to the cross-sectional view shown in FIG. 3. One of the ceramic substrates 31 forming the insulating layer 3 includes a first hole 301 and a second hole 302 filled by a first conductive layer 41 and a second conductive layer 42, respectively. The first conductive layer 41 is used as the positive electrode and connected with a first conductive film 21 below the first conductive layer 41 and the solar cell 5 on the first conductive layer 41. The solar cell 5 is then connected electrically with the second conductive layer 42, which is used as the negative electrode, via the conductive wire 6. Next, the second conductive layer 42 is connected electrically with a second conductive film 22 below the second conductive layer 42. By using the same structure, adjacent solar cells and a third conductive film 23 will hence form a complete serial connection. According to the above structure, any conductive wire 6 is connected electrically with any solar cell 5 and the adjacent conductive layer 4.

In other words, according to the preferred embodiment as described above, the insulating layer 3 is disposed on the glass substrate 1. The insulating layer 3 comprises multiple holes 30 located on the conductive film 2. These holes 30 can further correspond to different conductive films 2. According to the present invention, these holes 30 are used for connecting electrically the bottom surface of the conductive layer 4 and the conductive film 2 as well as connecting electrically the top surface of the conductive layer 2 with the solar cell 5. The method for connecting different conductive films 2, conductive layers 4, and solar cells 5 can be done correspondingly according to the general serial connection of electricity.

The basic structure of the conductive layer 4 includes the holes 30 filled with the insulating layer 3 such that the top and bottom surfaces thereof can be connected electrically with other devices. Compared with eh preferred embodiment of FIGS. 1 and 2, according to another preferred embodiment as shown in FIG. 3, the conductive layer 4 is further extended and enlarged towards the directions of the top and bottom sides of the insulating layer 3, so that the areas of the top and bottom surfaces of the conductive layer 4 are greater than the cross-sectional area of the hole 30. By using the structure, given the condition of smaller holes 30, larger areas can still be provided to connect electrically the conductive film 2 and the solar cells 5. In addition, complete contacts between the conductive layer 4 and the conductive film 2 and between the conductive layer 4 and the solar cells 5 can be ensured.

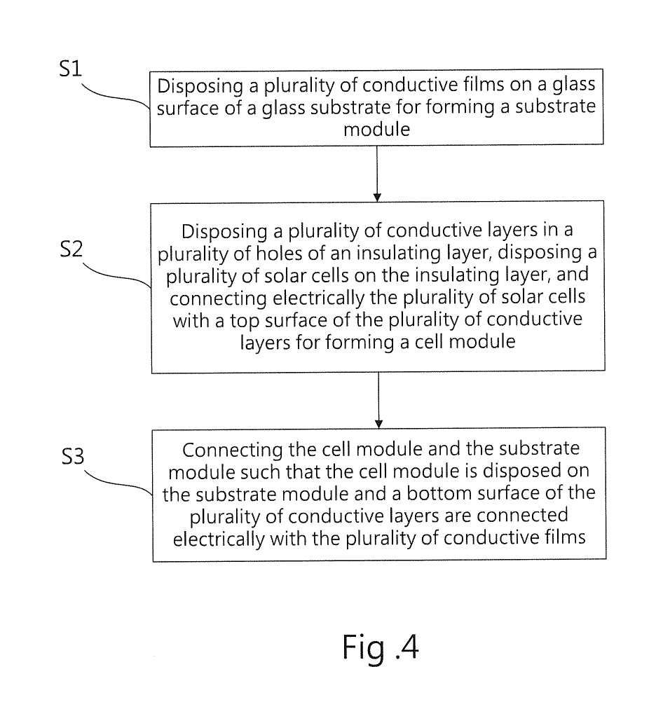

Based on the above description, please refer to FIG. 4. The method for packaging solar cell device according to the present invention can be organized as the following steps:

Step S1: Disposing a plurality of conductive films on a glass surface of a glass substrate for forming a substrate module;

Step S2: Disposing a plurality of conductive layers in a plurality of holes of an insulating layer, disposing a plurality of solar cells on the insulating layer, and connecting electrically the plurality of solar cells with a top surface of the plurality of conductive layers for forming a cell module; and

Step S3: Connecting the cell module and the substrate module such that the cell module is disposed on the substrate module and a bottom surface of the plurality of conductive layers are connected electrically with the plurality of conductive films.

In the above steps, with reference to FIG. 2, the order of preparing the substrate module 71 and the cell module 72 can be arbitrary. That is to say, the substrate module 71 and the cell module 72 can be manufactured individually and concurrently before connecting them. In the manufacturing process, it is not required to process the same substrate continuously and complete assembly of all devices sequentially. Thereby, substantial time can saved and the production efficiency can be improved. According to the present invention, in the step of disposing the conductive films on the surface of the glass substrate, methods such as screen printing, spray coating, electroplating, vapor deposition, or sputtering deposition can be adopted. In addition, in the step of connecting the cell module and the substrate module, thermally and electrically conductive paste or soldering can be used for connecting the two. After connecting repeatedly the substrate module and the cell module, a solar cell array can be assembled and thus forming a complete structure of power generation module.

As described in the above structure, the glass substrate can be replaced by other insulating materials, for example, an insulating high-polymer substrate. The insulating layer can be a ceramic substrate. Besides, the conductive layer and the conductive film can adopt conductive materials such as silver, gold, copper, aluminum, or tin.

To sum up, the present invention discloses in detail a method for packaging solar cell device and the structure thereof. By combining the glass substrate having the circuit and the ceramic substrate having the holes and transferring the electrodes from the front surface to the back surface using the ceramic substrate having the holes, a reliable packaging architecture is provided. The packaging architecture according to the present invention can eliminate the usage of connecting conductive wires and use glass as the substrate appropriately. Hence, the present invention is endowed with the advantages of low carbon emission, low cost, and high weather endurance.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A structure of solar cell device, comprising:
a glass substrate, disposing a plurality of conductive films on a glass surface;
an insulating layer, disposing on said glass substrate, and comprising a plurality of holes located on said plurality of conductive films;
a plurality of conductive layers, disposed in said plurality of holes, and having a bottom surface connected electrically with said plurality of conductive films; and
a plurality of solar cells, disposed on said insulating layer, and connected electrically with a top surface of said plurality of conductive layers.

2. The structure of solar cell device of claim 1, wherein said insulating layer is formed by one or more ceramic substrate.

3. The structure of solar cell device of claim 2, wherein the material of said ceramic substrate is aluminum oxide or aluminum nitride.

4. The structure of solar cell device of claim 1, wherein the area of said top surface of said plurality of conductive layers is greater than the cross-sectional area of said plurality of holes.

5. The structure of solar cell device of claim 1, wherein the area of said bottom surface of said plurality of conductive layers is greater than the cross-sectional area of said plurality of holes.

6. The structure of solar cell device of claim 1, and further comprising a plurality of conductive wires, any of said plurality of conductive wires connected electrically with any of said plurality of solar cells and said plurality of adjacent conductive layers.

7. A structure of solar cell device, comprising:
an insulating high-polymer substrate, disposing a plurality of conductive films on an insulating high-polymer surface;
an insulating layer, disposing on said insulating high-polymer substrate, and comprising a plurality of holes located on said plurality of conductive films;
a plurality of conductive layers, disposed in said plurality of holes, and having a bottom surface connected electrically with said plurality of conductive films; and
a plurality of solar cells, disposed on said insulating layer, and connected electrically with a top surface of said plurality of conductive layers.

8. A method for packaging solar cell device of claim 1, comprising steps of:
disposing a plurality of conductive films on a glass surface of a glass substrate for forming a substrate module;
disposing a plurality of conductive layers in a plurality of holes of an insulating layer, disposing a plurality of solar cells on said insulating layer, and connecting electrically said plurality of solar cells with a top surface of said plurality of conductive layers for forming a cell module; and
connecting said cell module and said substrate module such that said cell module is disposed on said substrate module and a bottom surface of said plurality of conductive layers are connected electrically with said plurality of conductive films;
where the order for preparing said substrate module and said cell module can be arbitrary.

9. The method for packaging solar cell device of claim 8, wherein said step of disposing said plurality of conductive films on said glass surface of said glass substrate adopts screen printing, spray coating, electroplating, vapor deposition, or sputtering deposition methods.

10. The method for packaging solar cell device of claim 8, wherein said step of connecting said cell module and said substrate module adopts thermally and electrically conductive paste or soldering methods.

11. A method for packaging solar cell device of claim 7, comprising steps of:
disposing a plurality of conductive films on an insulating high-polymer surface of an insulating high-polymer substrate for forming a substrate module;
disposing a plurality of conductive layers in a plurality of holes of an insulating layer, disposing a plurality of solar cells on said insulating layer, and connecting electrically said plurality of solar cells with a top surface of said plurality of conductive layers for forming a cell module; and
connecting said cell module and said substrate module such that said cell module is disposed on said substrate module and a bottom surface of said plurality of conductive layers are connected electrically with said plurality of conductive films;
where the order for preparing said substrate module and said cell module can be arbitrary.
